(19) United States
(12) Patent Application Publication
(10) Pub. No.: US 2011/0227173 A1
(43) Pub. Date: Sep. 22, 2011

(54) MEMS SENSOR WITH INTEGRATED ASIC PACKAGING

(75) Inventors: Bryan R. Seppala, Mahtomedi, MN (US); Jon B. DCamp, Savage, MN (US); Harlan L. Curtis, Champlin, MN (US); Chad Buss, Minneapolis, MN (US)

(73) Assignee: HONEYWELL INTERNATIONAL INC., Morristown, NJ (US)

(21) Appl. No.: 12/848,666

(22) Filed: Aug. 2, 2010

Related U.S. Application Data
(60) Provisional application No. 61/314,674, filed on Mar. 17, 2010.

(51) Int. Cl. H01L 29/84

(52) U.S. Cl. 257/415; 257/E29.324

(57) ABSTRACT

A sensor assembly comprises an integrated circuit (IC) substrate having an upper surface and operating circuitry, and a micro-electro-mechanical systems (MEMS) sensor die attached to the upper surface of the IC substrate in a stacked configuration. The MEMS sensor die in operative communication with the operating circuitry of the IC substrate. A seal ring surrounds an outer periphery of the upper surface of the IC substrate, and a seal cap is secured to the seal ring over the MEMS sensor die.

### CROSS-REFERENCE TO RELATED APPLICATIONS

This application claims the benefit of U.S. Provisional Patent Application Ser. No. 61/314,674, filed on Mar. 17, 2010, which is incorporated herein by reference.

### BACKGROUND

Micro-electro-mechanical systems (MEMS) devices are typically formed with semiconductor fabrication techniques to create small mechanical structures on a surface of a substrate such as a wafer. In the production of MEMS devices such as gyroscopes or accelerometers, such semiconductor fabrication techniques are often used to create a number of moving structures that can be used to sense displacement and/or acceleration in response to movement of the device about an input or rate axis. In navigational and communications systems, such moving structures can be used to measure and/or detect variations in linear and/or rotational motion of an object traveling through space.

The packaging of MEMS devices remains a significant challenge in the overall fabrication process. In many cases, MEMS dies include a MEMS side and a back side. The back side of the MEMS die is often bonded to the floor of a cavity in a MEMS package. Wire bond pads on the MEMS side of the MEMS die are typically wire bonded to bond pads in or along the MEMS package cavity. Finally, a package lid is typically secured to the top of the MEMS package to provide a hermitic seal for the MEMS package cavity. In some cases, the lid is secured in a vacuum or partial vacuum to provide a desired environment for the enclosed MEMS device.

Due to their size and composition, the mechanical structures of many MEMS devices are susceptible to damage in high-G applications, and from particles, moisture or other such contaminants that can become entrained within the MEMS package cavity. In addition, there can be difficulty in accurately regulating the pressure within the MEMS package cavity during the fabrication process, which can affect the performance characteristics of the MEMS device, often reducing its efficacy in detecting subtle changes in motion.

### SUMMARY

A sensor assembly comprises an integrated circuit (IC) substrate having an upper surface and operating circuitry, and a micro-electro-mechanical systems (MEMS) sensor die attached to the upper surface of the IC substrate in a stacked configuration. The MEMS sensor die is in operative communication with the operating circuitry of the IC substrate. A seal ring surrounds an outer periphery of the upper surface of the IC substrate, and a seal cap is secured to the seal ring over the MEMS sensor die.

### BRIEF DESCRIPTION OF THE DRAWINGS

Features of the present invention will become apparent to those skilled in the art from the following description with reference to the drawings. Understanding that the drawings depict only typical embodiments and are not therefore to be considered limiting in scope, the invention will be described with additional specificity and detail through the use of the accompanying drawings, in which:

FIG. 1 is a schematic perspective view of a sealed MEMS sensor assembly according to one embodiment;

FIG. 2A is a top view of an electronic device including a plurality of MEMS sensor assemblies attached to a substrate according to another embodiment;

FIG. 2B is a cross-sectional side view of the electronic device of FIG. 2A;

FIG. 3A is a top view of an electronic device including a plurality of MEMS sensor dies attached to an application-specific integrated circuit (ASIC) substrate according to a further embodiment; and

FIG. 3B is a cross-sectional side view of the electronic device of FIG. 3A.

### DETAILED DESCRIPTION

In the following detailed description, embodiments are described in sufficient detail to enable those skilled in the art to practice the invention. It is to be understood that other embodiments may be utilized without departing from the scope of the invention. The following detailed description is, therefore, not to be taken in a limiting sense.

The embodiments disclosed herein relate to an electronic device including one or more micro-electro-mechanical systems (MEMS) sensors with integrated processing circuitry. In one embodiment, the electronic device includes a MEMS sensor die attached to an application-specific integrated circuit (ASIC) die in a stacked MEMS/ASIC assembly. The ASIC die is the base of the assembly, with the MEMS die being attached to an upper surface of the ASIC die.

The stacked MEMS/ASIC assembly provides for a decreased footprint for the MEMS sensor. The ASIC die provides the MEMS sensor with integrated electronics that allow for more complete functional testing of the sensor. In other embodiments, other processing circuitry can be used in place of the ASIC die, such a field programmable gate array (FPGA) die, or other programmable logic device.

During fabrication, the MEMS sensor die, such as a gyroscope or accelerometer, can be attached to the ASIC die by flip chip bonding, or can be die attached with an adhesive and wire bonded. For example, a vacuum wafer level MEMS die can be flip chip attached directly to the ASIC die, or attached to the front of the ASIC die and wirebonded. The ASIC die can include input/output (I/O) pads relocated for flip chip bonding the MEMS die to the ASIC die, or I/O pads relocated around the MEMS die for wire bonding. One or more operational amplifiers can also be added onto the ASIC die in the same manner.

The ASIC die can be fabricated with thru vias such as silicon vias in order to allow for surface mounting of the MEMS sensor onto a substrate. The ASIC die can also be fabricated with a seal ring around the perimeter of the die that is suitable for hermetic or vacuum sealing. For example, for a non-vacuum wafer level MEMS die, a seal ring can be deposited around the MEMS die bond site on the ASIC die in order to vacuum seal the MEMS die. A seal cap is attached to the upper surface of the ASIC die with the seal ring, which can be solder or glass frit. When a gyroscope die is utilized in the MEMS sensor, a getter can be added to the inside of the cover. Once the cover is sealed on the ASIC die, solder balls can be attached to the bottom of the ASIC die in contact with the vias to provide for surface mounting the ASIC die on a substrate. Testing of the MEMS sensor device can be done before or after the ball attachment.

The substrate for the MEMS sensor can be made of a semiconductor wafer such as a silicon wafer using standard semiconductor top metal processing, and can include aluminum lines with silicon oxide dielectric. Standard surface mount resistors and capacitors can also be attached to the substrate along with the MEMS/ASIC assembly. In another embodiment, thin film resistors can be built into the substrate which can be laser trimmed for tuning.

Bond pads can be formed on the substrate for flip chip bonding of the MEMS die, ASIC die, and operational amplifiers, as well as to bond a surface mount edge connector and discrete components. For a non-vacuum wafer level MEMS die, a die shrink design can be used to minimize substrate area.

Gun hard requirements may require an underfill of the ASIC die and/or operational amplifiers. If the coefficient of thermal expansion (CTE) of the substrate matches the die, the underfill may not be necessary. The CTE match of the MEMS die and substrate should also eliminate drift issues caused by CTE mismatch.

The present MEMS sensor assembly has various benefits, including multiple levels of interconnect, increased reliability, increased performance, and decreased assembly cost over conventional MEMS devices.

Various embodiments of the MEMS sensor assembly are described in further detail as follows with reference to the drawings.

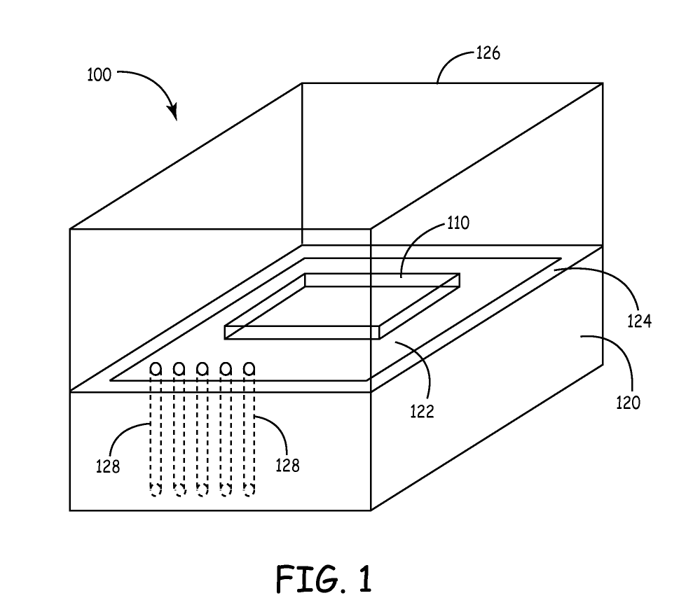

Referring now to FIG. 1, an illustrative method of packaging a MEMS device will now be described. The illustrative method begins with the steps of providing a MEMS die, generally shown at 100, and in the embodiment shown, having a MEMS gyroscope device 110 secured to a substrate 120. MEMS gyroscopes are typically used to sense angular displacement or movement.

FIG. 1 depicts a sealed sensor assembly 100 according to one embodiment. The sensor assembly 100 includes a MEMS sensor die 110 packaged with an integrated circuit (IC) substrate 120 in a stacked configuration. The IC substrate 120 has an upper surface 122 and operating circuitry (not shown). The MEMS sensor die 110 is in operative communication with the operating circuitry of IC substrate 120. The IC substrate 120 can be a special purpose processor such as an ASIC, FPGA, Magnetic Random Access Memory (MRAM), Erasable Programmable Read Only Memory (EPROM), or the like.

The MEMS sensor die 110 can include one or more MEMS inertial sensors. For example, at least one of the MEMS inertial sensors can be a gyroscope or an accelerometer. The MEMS sensor die 110 may be composed of a variety of materials including, for example, quartz, silicon, gallium arsenide, germanium, glass, and the like. The MEMS sensor die 110 can be flip chip bonded to upper surface 122 of IC substrate 120 by standard techniques. In this case, the IC substrate 120 includes bond pads in the center of the die under MEMS sensor die 110 to allow for flip chip bonding.

The IC substrate such as an ASIC includes operating circuitry for sensing, signal conditioning, and control of the MEMS inertial sensors, with common functional building blocks for operating the sensors being combined and shared.

A seal ring 124 surrounds MEMS sensor die 110 along an outer periphery of upper surface 122 of IC substrate 120. A seal cap 126 is secured to the seal ring over MEMS sensor die 110. The seal cap 126 allows for vacuum sealing or hermetic sealing, with or without a backfilled inert gas, of MEMS sensor die 110. When a gas backfill is utilized, a dry inert gas such as argon is introduced at a specified low pressure into a vacuum or hermetic cavity for the MEMS sensor die. The seal cap 126 can be made of glass, silicon, ceramic, or metal.

The seal ring 124 may be formed by standard deposition techniques. For example, when a soldering process is used to bond the seal cap 126 to IC substrate 120, seal ring 124 may be composed of gold, lead, tin, aluminum, platinum, or other suitable materials or combination of materials, suitable for providing a good wetting surface for the solder. In another approach, a glass frit seal may be used along seal ring 124 to bond seal cap 126 to IC substrate 120. In another example, a thermo-compression bonding process can be used to bond seal cap 126 to IC substrate 120. In this case, seal ring 124 includes a bonding material such as gold, silver, lead, tin, aluminum, or the like, which after sufficient heat and pressure are applied, form the desired thermo-compression bond.

A getter material can be deposited on an inner surface of seal cap 126 as needed. The getter material may zirconium, titanium, boron, cobalt, calcium, strontium, thorium, combinations thereof, and the like. The getter material may be selected to chemically absorb some or all of the gases that may outgas into the cavity under seal cap 26, such as water vapor, oxygen, carbon monoxide, carbon dioxide, nitrogen, hydrogen, and/or other gases, as desired.

Thru vias 128 such as silicon vias can be formed in IC substrate 120 to allow for surface mounting of sensor assembly 100 onto an underlying substrate. For example, vias 128 can be used to attach solder balls (not shown) to the bottom of IC substrate 120 to allow surface mount attachment to an underlying substrate such as a silicon substrate or a printed circuit board. The vias 128 allow the sensor assembly 100 to be tested before attaching it to a substrate.

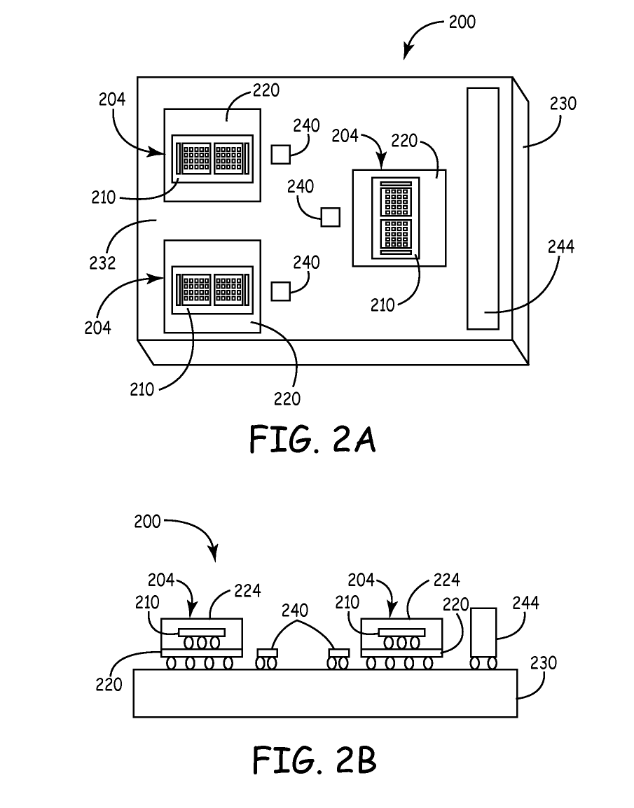

FIGS. 2A and 2B illustrate an electronic device 200 such as a multi-axis sensing device according to one embodiment. The device 200 includes multiple sensor assemblies 204, which are similar to sensor assembly 100 in FIG. 1. Accordingly, each sensor assembly 204 includes a MEMS sensor die 210 packaged with an IC substrate 220 in a stacked configuration. The IC substrate 220 can be a special purpose processor such as an ASIC. Each MEMS sensor die 210 can include MEMS inertial sensors such as a gyroscope or an accelerometer. The MEMS sensor dies 210 are vacuum sealed or hermetically sealed, with or without a backfilled inert gas, with a seal cap 224. The seal cap 224 can be attached to IC substrate 220 with a solder (e.g., 80/20 Au/Sn) or a glass frit.

The sensor assemblies 204 are mounted to a substrate 230 on an upper surface 232 thereof, such as through flip chip bonding using a ball grid array. Alternatively, the sensor assemblies 204 can be mounted to upper surface 312 by wirebonding. The substrate 230 can be a printed circuit board (PCB), a larger ASIC, a multichip ceramic interconnect board, or the like. A plurality of operational amplifiers 240 are also mounted on upper surface 232 of substrate 210, with each operational amplifier adjacent to MEMS sensor die 210. An edge connector 244 is mounted on upper surface 232 of substrate 230 at one end thereof. The edge connector 244 provides electronic device 200 with an input/output (I/O) coupling to outside electronics such as in a rate sensor or inertial measurement unit (IMU). Surface mount resistors and capacitors can also be mounted throughout open areas on upper surface 232 of substrate 230 as needed.

As shown in FIG. 2A, three sensor assemblies 204 are arranged on substrate 230 to provide a 3-axis (x, y, z) sensing device. For example, in one embodiment, each MEMS sensor die 210 includes a gyroscope to produce a 3-axis angular rate sensor. In another embodiment, each MEMS sensor die 210 includes an accelerometer to produce a 3-axis acceleration sensor. The 3-axis angular rate sensor and acceleration sensor can be employed together in an IMU, which can provide inertial navigation for aircraft, spacecraft, or watercraft. The 3-axis angular rate sensor can also be employed in a rate sensing device, or a sensory control unit.

In alternative implementations, one, two, or four or more sensor assemblies 204 can be mounted on substrate 230 as desired. For example, in one embodiment, six sensor assemblies are mounted on substrate 230, including three angular rate sensors and three acceleration sensors, which can be implemented in an IMU.

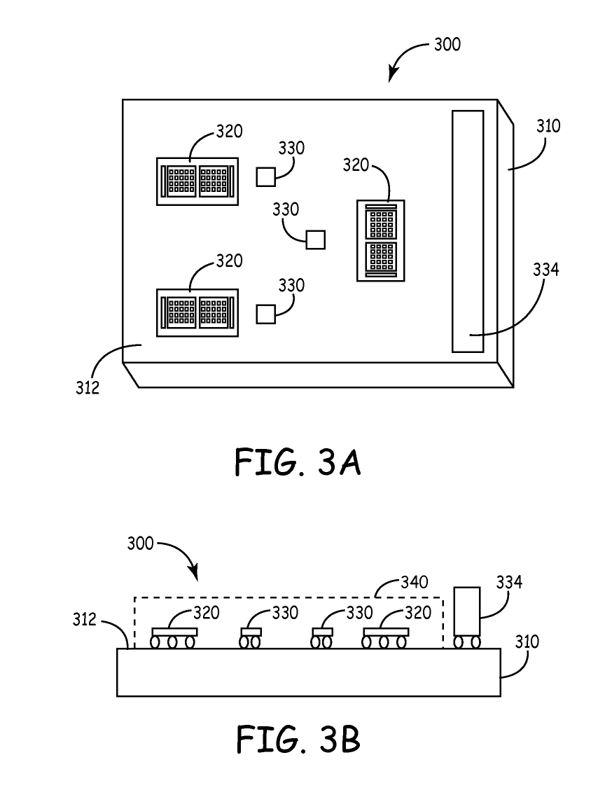

FIGS. 3A and 3B illustrate an electronic device 300 such as a multi-axis sensing device according to another embodiment. The device 300 includes an ASIC substrate 310 having an upper surface 312 and processing circuitry (not shown). In an alternative embodiment, the ASIC substrate can be substituted with a field programmable gate array.

A plurality of MEMS sensor dies 320 are mounted on upper surface 312 of ASIC substrate 310, such as through flip chip bonding using a ball grid array. Alternatively, the MEMS sensor dies 320 can be mounted to upper surface 312 by wirebonding. Each MEMS sensor die 320 can include MEMS inertial sensors such as a gyroscope or an accelerometer.

Other electronic components can be mounted to upper surface 312 of ASIC substrate 310 in open areas. For example, a plurality of operational amplifiers 330 can be attached to upper surface 312, with each operational amplifier adjacent to a MEMS sensor die 320. An edge connector 334 can also be mounted on upper surface 312 of ASIC substrate 310 at one end thereof. Surface mount resistors and capacitors can also be mounted throughout open areas on upper surface 312 as needed.

As shown in FIG. 3A, three MEMS sensor dies 320 are arranged on ASIC substrate 310 to provide a 3-axis (x, y, z) sensing device. For example, in one embodiment, each MEMS sensor die 320 includes a gyroscope to produce a 3-axis angular rate sensor. In another embodiment, each MEMS sensor die 320 includes an accelerometer to produce a 3-axis acceleration sensor. The 3-axis angular rate sensor and acceleration sensor can be employed together in an IMU. The 3-axis angular rate sensor can also be employed in a rate sensing device, or a sensory control unit.

In alternative implementations, one, two, or four or more MEMS sensor dies 320 can be mounted on ASIC substrate 310. For example, in one embodiment, six MEMS sensor dies are mounted on ASIC substrate 310, including three gyroscopes and three accelerometers. In this configuration, electronic device 300 which can be utilized in an IMU.

In another embodiment, a sealing cover 340 can be applied to ASIC substrate 310 over upper surface 212 to vacuum seal, hermetically seal, or gas backfilled seal MEMS sensor dies 320 when the sensor dies 320 are not presealed.

The present invention may be embodied in other specific forms without departing from its essential characteristics. The described embodiments are to be considered in all respects only as illustrative and not restrictive. The scope of the invention is therefore indicated by the appended claims rather than by the foregoing description. All changes that come within the meaning and range of equivalency of the claims are to be embraced within their scope.

What is claimed is:

1. A sensor assembly, comprising:
an integrated circuit (IC) substrate having an upper surface and operating circuitry;
a micro-electro-mechanical systems (MEMS) sensor die attached to the upper surface of the IC substrate in a stacked configuration, the MEMS sensor die in operative communication with the operating circuitry of the IC substrate;
a seal ring surrounding an outer periphery of the upper surface of the IC substrate; and
a seal cap secured to the seal ring over the MEMS sensor die.

2. The sensor assembly of claim 1, wherein the IC substrate comprises an application-specific integrated circuit, a field programmable gate array, a magnetic random access memory, or an erasable programmable read only memory.

3. The sensor assembly of claim 1, wherein the MEMS sensor die comprises at least one MEMS inertial sensor.

4. The sensor assembly of claim 3, wherein the MEMS inertial sensor comprises a gyroscope.

5. The sensor assembly of claim 3, wherein the MEMS inertial sensor comprises an accelerometer.

6. The sensor assembly of claim 1, further comprising a plurality of vias extending thru the IC substrate.

7. The sensor assembly of claim 1, wherein the MEMS sensor die is vacuum sealed with the seal cap, with or without a backfilled inert gas.

8. The MEMS sensor assembly of claim 1, wherein the MEMS sensor die is hermetically sealed with the seal cap, with or without a backfilled inert gas.

9. An electronic device, comprising:
a supporting substrate having a top surface;
a plurality of sensor assemblies mounted on the top surface of the supporting substrate, each of the sensor assemblies comprising:
an integrated circuit (IC) die having a first surface and an opposing second surface, the first surface of the IC die coupled to the top surface of the supporting substrate;
a micro-electro-mechanical systems (MEMS) sensor die operatively coupled to the IC die at the second surface in a die stack configuration,
a seal ring surrounding an outer periphery of second surface of the IC die; and
a seal cap secured to the seal ring over the MEMS sensor die.

10. The electronic device of claim 9, wherein the IC die comprises an application-specific integrated circuit, a field programmable gate array, a magnetic random access memory, or an erasable programmable read only memory.

11. The electronic device of claim 9, wherein the MEMS sensor die comprises at least one MEMS inertial sensor.

12. The electronic device of claim 11, wherein the MEMS inertial sensor comprises a gyroscope or an accelerometer.

13. The electronic device of claim 9, wherein the MEMS sensor die is vacuum sealed or hermetically sealed with the seal cap, with or without a backfilled inert gas.

14. The electronic device of claim 9, further comprising a plurality of operational amplifiers mounted to the second surface of the IC die, each of the operational amplifiers coupled to a respective MEMS sensor die.

15. The electronic device of claim 9, further comprising an edge connector mounted on the top surface of the supporting substrate.

16. The electronic device of claim 6, wherein the electronic device is implemented in an inertial measurement unit, a rate sensing device, or a sensory control unit.

17. A multi-axis sensing device, comprising:
an application-specific integrated circuit (ASIC) substrate having a top surface and operating circuitry;
a plurality of micro-electro-mechanical systems (MEMS) inertial sensor dies attached to the top surface of the ASIC substrate in a stacked configuration, the MEMS inertial sensor dies coupled with the operating circuitry of the ASIC substrate; and
a plurality of operational amplifiers mounted to the top surface of the ASIC substrate, each of the operational amplifiers coupled to a respective one of the MEMS sensor dies.

18. The multi-axis sensing device of claim 17, wherein each of the MEMS inertial sensor dies comprises a gyroscope or an accelerometer.

19. The multi-axis sensing device of claim 17, further comprising a sealing cover secured to the top surface of the ASIC substrate to vacuum seal or hermetically seal the MEMS inertial sensor dies, with or without a backfilled inert gas.

20. The multi-axis sensing device of claim 17, wherein the sensing device is implemented in an inertial measurement unit, a rate sensing device, or a sensory control unit.
